(19) United States
(12) Patent Application Publication
(10) Pub. No.: US 2016/0079040 A1
(43) Pub. Date: Mar. 17, 2016

(54) Plasma Processing Devices Having a Surface Protection Layer

(71) Applicant: Samsung Electronics Co., Ltd., Suwon-si (KR)

(72) Inventors: MyoungSoo Park, Seongnam-si (KR); Hakyoung Kim, Bucheon-si (KR); Yumi Sung, Namyangju-si (KR); Seungkyu Lim, Uiwang-si (KR)

(21) Appl. No.: 14/794,383

(22) Filed: Jul. 8, 2015

(30) Foreign Application Priority Data
Sep. 11, 2014 (KR) 10-2014-0120478

(51) Int. Cl. H01J 37/32; H01L 21/67

(52) U.S. Cl. CPC H01J 37/32477; H01J 37/3244; H01J 37/32642; H01L 21/67069; H01J 2237/334; H01J 2237/0203

(57) ABSTRACT

Plasma processing devices may include a process chamber body, a substrate support unit in a lower portion of the process chamber body, and a window part in an upper portion of the process chamber body. The window part may include a base layer and a surface protection layer on the base layer and configured to face the substrate support unit. The surface protection layer may include an oxide having a columnar structure.

### CROSS-REFERENCE TO RELATED APPLICATION

This application claims priority under 35 U.S.C. §119 to Korean Patent Application No. 10-2014-0120478 filed on Sep. 11, 2014, in the Korean Intellectual Property Office, the disclosure of which is incorporated by reference herein in its entirety.

### BACKGROUND

Embodiments of the present inventive concepts relate to plasma processing devices for a process of fabricating semiconductor devices.

As semiconductor devices gradually achieve higher integration, an inductively coupled plasma processing device configured to obtain high density plasma may be used.

However, as a high voltage may be needed to generate high density plasma, a window part in the inductively coupled plasma processing device may be damaged and generate particles.

The particles may cause not only a decreased yield of the semiconductor devices, but also a reduced lifetime of the plasma processing device.

### SUMMARY

A plasma processing device in accordance with embodiments of the present inventive concepts may include a process chamber body, a substrate support unit in a lower portion of the process chamber body, and a window part in an upper portion of the process chamber body. The window part may include a base layer and a surface protection layer on the base layer and configured to face the substrate support unit. The surface protection layer may include an oxide having a columnar structure.

A plasma processing device in accordance with embodiments of the present inventive concepts may include a process chamber body, a window part in an upper portion of the process chamber body. The window part may be configured to prevent contamination in the upper portion of the process chamber body, and may be configured to maintain a processing space of the process chamber body in a vacuum state. The window part may include a base layer and a surface protection layer on the base layer. The surface protection layer may include an oxide layer formed by a vapor deposition process.

A plasma processing device in accordance with embodiments of the present inventive concepts may include a process chamber body having a first surface protection layer on a surface of the process chamber body, and a window part in an upper portion of the process chamber body. The window part may include a base layer and a second surface protection layer formed on a surface of the base layer. The second surface protection layer may include and oxide layer formed by a vapor deposition process.

Detailed items in other embodiments of the present inventive concepts will be described more in detail through detailed descriptions of the present inventive concepts.

### BRIEF DESCRIPTION OF THE DRAWINGS

The foregoing and other features and advantages of the present inventive concepts will be apparent from the more particular description of embodiments of the present inventive concepts, as illustrated in the accompanying drawings in which like reference characters refer to the same parts throughout the different views. The drawings are not necessarily to scale, emphasis instead being placed upon illustrating the principles of the present inventive concepts. In the drawings:

FIG. 1 is an overall block diagram of plasma processing devices in accordance with embodiments of the present inventive concepts;

FIG. 2 is a flow chart illustrating methods of manufacturing plasma processing devices in accordance with embodiments of the present inventive concepts;

FIGS. 3A and 3B illustrate a process of manufacturing a window part applicable to FIG. 2;

FIG. 4 is a scanning electron microscope (SEM) image illustrating an example surface structure of a conventional surface protection layer;

FIG. 5 is a SEM image illustrating an example surface state after exposing the surface protection layer in FIG. 4 to a plasma etching environment;

FIG. 6 is a SEM image illustrating an example surface structure of a surface protection layer formed in accordance with embodiments of the present inventive concepts;

FIG. 7 is a SEM image illustrating an example surface state after exposing the surface protection layer in FIG. 6 to a plasma etching environment;

FIG. 8 is a SEM image illustrating a columnar structure of an yttrium oxide layer;

FIG. 9 is an overall block diagram of plasma processing devices in accordance with embodiments of the present inventive concepts; and

FIG. 10 is a flow chart illustrating methods of manufacturing plasma processing devices in accordance with embodiments of the present inventive concepts.

### DETAILED DESCRIPTION

Advantages and features of the present inventive concepts and methods of achieving them will be made apparent with reference to the accompanying figures and the embodiments to be described below in detail. However, these present inventive concepts should not be limited to the embodiments set forth herein and may be construed as various embodiments in different forms. Rather, these embodiments are provided so that disclosure of the present inventive concepts is thorough and complete, and fully conveys the present inventive concepts to those of ordinary skills in the art. The present inventive concepts are defined by the appended claims.

The terminology used herein is only intended to describe embodiments of the present inventive concepts and not intended to limit the scope of the present inventive concepts. As used herein, the singular forms “a,” “an,” and “the” are intended to include the plural forms as well, unless specifically indicated otherwise. The terms “comprises,” “comprising,” “includes,” and/or “including” and variants thereof, when used herein, specify the presence of mentioned elements, steps, operations, and/or devices, but do not preclude the presence or addition of one or more of other elements, steps, operations, and/or devices.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

Further, like numbers refer to like elements throughout the entire text herein. Thus, the same or similar numbers may be described with reference to other figures even if those numbers are neither mentioned nor described in the corresponding figures. Further, elements that are not denoted by reference numbers may be described with reference to other figures.

Spatially relative terms, such as “below,” “beneath,” “lower,” “above,” “upper,” and/or the like, may be used herein to easily describe the correlation between one device or element and another device or other element as illustrated in the figures. The spatially relative terms should be understood as the terms that include different orientations of the device in additional usage or operation of the orientations illustrated in the figures. For example, when the device illustrated in the figures is turned over, the device described as disposed “below” or “beneath” another device may be disposed “above” the other device. Accordingly, the term “below” or “beneath” may include both orientations of below and above. The device may be oriented at other orientations, and the spatially relative terms used herein may be interpreted accordingly.

Further, embodiments are described herein with reference to cross-sectional views and/or plan views that are idealized schematic views of the present inventive concepts. The thicknesses of layers and parts in the figures are overstated for the effective description of technical content. Thus, shapes of the schematic views may vary according to manufacturing techniques and/or tolerances. Therefore, the embodiments of the present inventive concepts are not limited to the particular shapes illustrated herein but are to include deviations in shapes formed in accordance with the manufacturing process. For example, an etched region illustrated as a rectangular shape may be a rounded or certain curvature shape. Thus, the regions illustrated in the figures are schematic in nature, and the shapes of the regions illustrated in the figures are intended to illustrate particular shapes of regions of devices and not intended to limit the scope of the present inventive concepts.

Plasma processing devices in accordance with embodiments of the present inventive concepts and methods of manufacturing the same will be described with reference to the accompanying drawings.

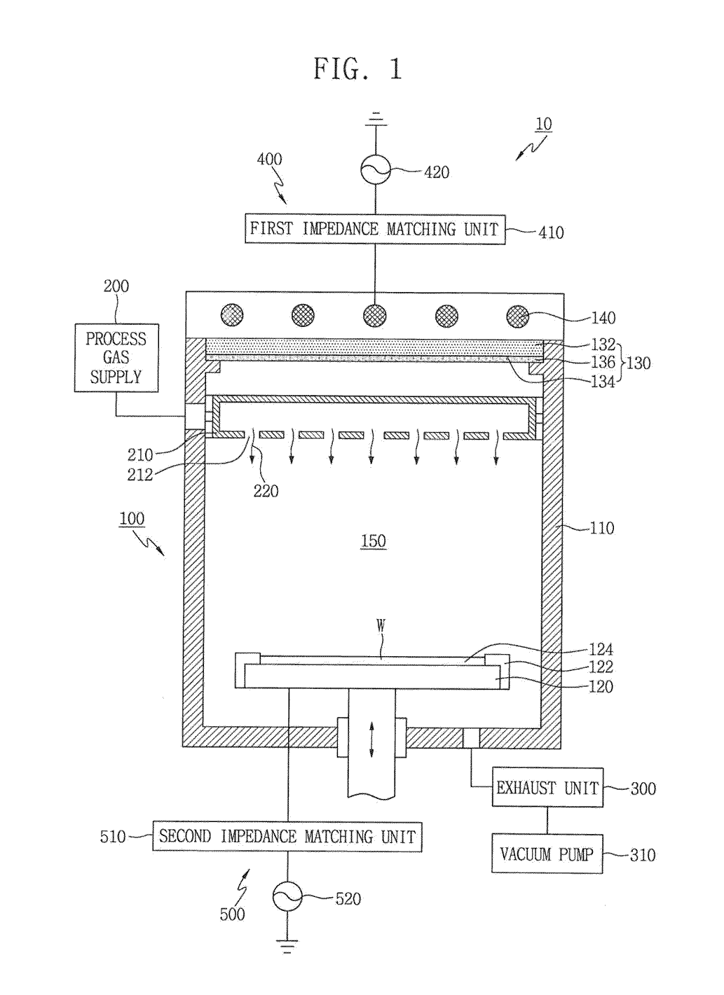

FIG. 1 illustrates an overall block diagram of plasma processing devices in accordance with embodiments of the present inventive concepts.

Referring to FIG. 1, a plasma processing device 10 in accordance with embodiments of the present inventive concepts may include a process chamber 100, a process gas supply 200, an exhaust unit 300, an upper power supply 400, and a lower power supply 500.

The process chamber 100 may include a process chamber body 110 configured to provide a processing space 150 for a plasma etching process, a substrate support unit 120 wherein a substrate such as a wafer 124 is supported and seated to perform a plasma etching process, a window part 130 configured to protect an upper portion of the process chamber body 110 and maintain a vacuum state by isolating the processing space 150 from external air, and an inductively coupled plasma (ICP) antenna 140 configured to supply a magnetic field to the processing space 150 in the process chamber body 110 to generate plasma.

In some embodiments, the process chamber body 110 may include quartz.

The substrate support unit 120 may include an electrostatic chuck capable of holding the wafer 124 through an electrostatic force. The electrostatic chuck may include a heater. The substrate support unit 120 may include a guide ring 122 to support the wafer 124 stably. The substrate support unit 120 may be formed to move up and down so as to expose the wafer 124 to an optimum plasma environment. The substrate support unit 120 may be connected to the lower power supply 500 that is configured to supply a bias voltage to ions escaping from the plasma so as to have a sufficiently high energy for collision with a surface of the wafer 124.

The window part 130 may include a base layer 132 as a main component, and a surface protection layer 136 formed on a surface 134 of the base layer 132 and configured to protect the base layer 132 from an external environment.

In some embodiments, the base layer 132 may have a surface roughness that can be measured. One measure of surface roughness is Rₐ, the arithmetic mean roughness, as determined by ASME B46.1. Rₐ is the average of the absolute value of profile heights over a given length (area). The base layer 132 may include a material layer having a surface 134 with a surface roughness, Rₐ, of 1 μm or less. Those skilled in the art will recognize that other standards of surface roughness could be used (e.g., R_{q}, Rₛₖ, Rₖᵤ, and/or R_{z}, among others.) The base layer 132 may include a material layer other than an organic material layer of plastic. The base layer 132 may include an aluminum oxide layer (e.g., Al₂O₃: alumina), an aluminum layer, a quartz layer, an oxide layer, and/or a nitride layer, among others.

As the surface protection layer 136 is a dielectric coating layer, the surface protection layer 136 may include a ceramic coating layer. The surface protection layer 136 may include a material layer having a porosity of 1% or less. The surface protection layer 136 may include an yttrium oxide (e.g., Y₂O₃) layer and/or a material layer containing carbon.

The surface protection layer 136 may be formed on a surface 134 of the base layer 132. The surface protection layer 136 may be formed on the surface 134 of the base layer 132 using a chemical vapor deposition (CVD) or physical vapor deposition (PVD) method. The surface protection layer 136 may be formed to have a thickness of 5 μm to 30 μm at a temperature of 100° C. to 600° C.

The window part 130 may be mounted so that the surface protection layer 136 is exposed to the processing space 150 of the process chamber 100. The window part 130 may be formed to have a plate shape forming a ceiling of the process chamber body 110. The window part 130 may be mounted to face the substrate support unit 120 in the process chamber 100.

The ICP antenna 140 may be formed above the window part 130. The ICP antenna 140 may include a concentrically wound coil structure and/or a helically wound coil structure.

The ICP antenna 140 may be connected to the upper power supply 400. When a power source is supplied from the upper power supply 400 to the ICP antenna 140, an induced magnetic field is generated in a coil thereof after an electric field in the coil is changed. Accordingly, a second induced current is generated in the processing space 150 of the process chamber 100 to generate plasma.

The process gas supply 200 may supply a process gas to the processing space 150 through a sidewall of the process chamber body 110. The process gas supply 200 may include a shower head 210 disposed above the substrate support unit 120 in the process chamber body 110. The shower head 210 may include a plurality of process gas injection nozzles 212 configured to inject a process gas 220 into the processing space 150.

The exhaust unit 300 may exhaust the process gas 220 and particles from the processing space 150 to the outside after a plasma etching process is completed. The exhaust unit 300 may include a vacuum pump 310 configured to exhaust a gas from the processing space 150.

The upper power supply 400 may supply a power source to the ICP antenna 140. The upper power supply 400 may include a first impedance matching unit 410 and a first power supply 420.

The lower power supply 500 may supply a bias voltage to the substrate support unit 120. The lower power supply 500 may include a second impedance matching unit 510 and a second power supply 520.

Methods of manufacturing plasma processing devices in accordance with embodiments of the present inventive concepts will be described with reference to the FIGS. 1, 2, 3A, and 3B.

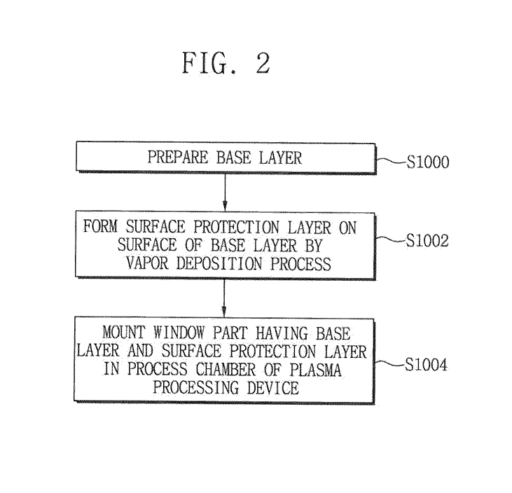

FIG. 2 illustrates a flow chart describing methods of manufacturing plasma processing devices in accordance with embodiments of the present inventive concepts.

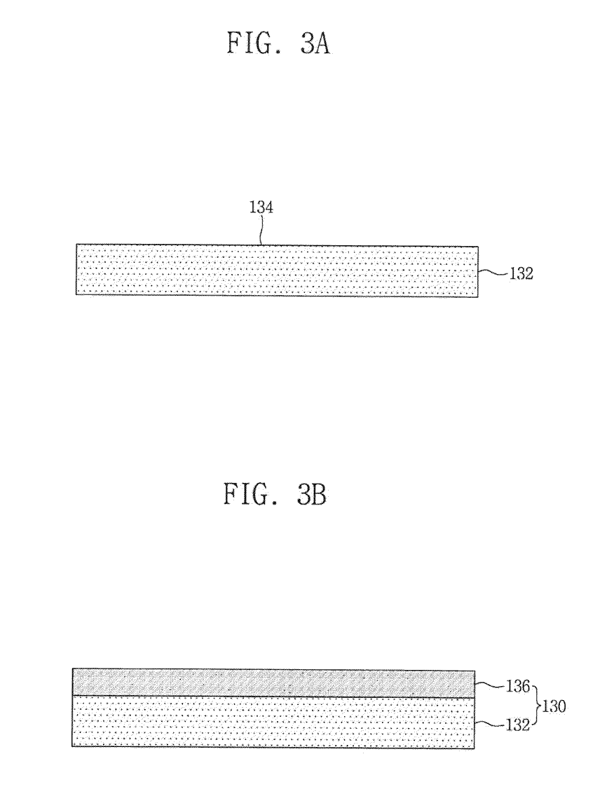

FIGS. 3A and 3B illustrate a process of manufacturing the window part applicable to FIG. 2.

Referring to FIGS. 2 and 3A, methods of manufacturing plasma processing devices 10 in accordance with embodiments of the present inventive concepts may include preparing a base layer 132 (S1000).

The base layer 132 may be formed with a material layer having a surface 134 with a surface roughness, Rₐ, of 1 μm or less.

The base layer 132 may include a material layer other than an organic material layer of plastic. The base layer 132 may include an aluminum oxide layer, an aluminum layer, a quartz layer, an oxide layer, and/or a nitride layer, among others.

Referring to FIGS. 2 and 3B, the method may include a forming a surface protection layer 136 configured to protect the base layer 132 from an external environment on a surface of a base layer 132 having a surface roughness, Rₐ, of 1 μm or less through a vapor deposition process (S1002).

The surface protection layer 136 may be formed as a dielectric coating layer. The surface protection layer 136 may be formed with a ceramic coating layer. The surface protection layer 136 may include an yttrium oxide (e.g., Y₂O₃) layer and/or a material layer containing carbon. The surface protection layer 136 may be formed with a material layer having a porosity of 1% or less.

The surface protection layer 136 may be formed by a CVD and/or a PVD process.

When the surface protection layer 136 is formed by a CVD process, a process temperature may be maintained at 100° C. or more. In some embodiments, when forming the surface protection layer 136, a process temperature may be maintained in a range of 100° C. to 600° C., and a vapor deposition thickness may be formed in a range of 5 μm to 30 μm. In some embodiments, when forming the surface protection layer 136, a process temperature may be maintained in a range of 400° C. to 600° C., and a vapor deposition thickness may be formed in a range of 5 μm to 15 μm.

When the surface protection layer 136 is formed by a PVD process, a process temperature may be maintained at 100° C. or more. In some embodiments, when forming the surface protection layer 136, a process temperature may be maintained in a range of 100° C. to 600° C., and a vapor deposition thickness may be formed in a range of 5 μm to 30 μm. In some embodiments, when forming the surface protection layer 136, a process temperature may be maintained in a range of 400° C. to 600° C., and a vapor deposition thickness may be formed in a range of 5 μm to 15 μm.

Therefore, when a CVD or a PVD method is applied, a high density surface protection layer 136 with few air holes or cracks may be formed on a surface 134 of the base layer 132. In some embodiments, a high density surface protection layer 136 formed by the CVD or PVD method may be formed without air holes or cracks on the surface 134 of the base layer 132.

Again, referring to FIGS. 1 and 2, the method may include mounting a window part 130 having a surface protection layer 136 formed on a surface 134 of a base layer 132 in a process chamber 100 of a plasma processing device 10 (S1004).

The window part 130 may be mounted to form a ceiling of a process chamber body 110. The window part 130 may be formed in an upper portion of the processing space 150 to face the substrate support unit 120. The window part 130 may be mounted to have a surface protection layer 136 exposed to the processing space 150.

A plasma etching process may be performed on a wafer 124 and be processed using a plasma processing device 10 mounted with the window part 130 having the base layer 132 and the surface protection layer 136.

The installation of a window part 130 with a high density surface protection layer 136 deposited through a vapor deposition process in a process chamber 100 of a plasma processing device 10 may resolve or reduce damage to the window part 130 caused by a generation of particles from high energy ion sputtering.

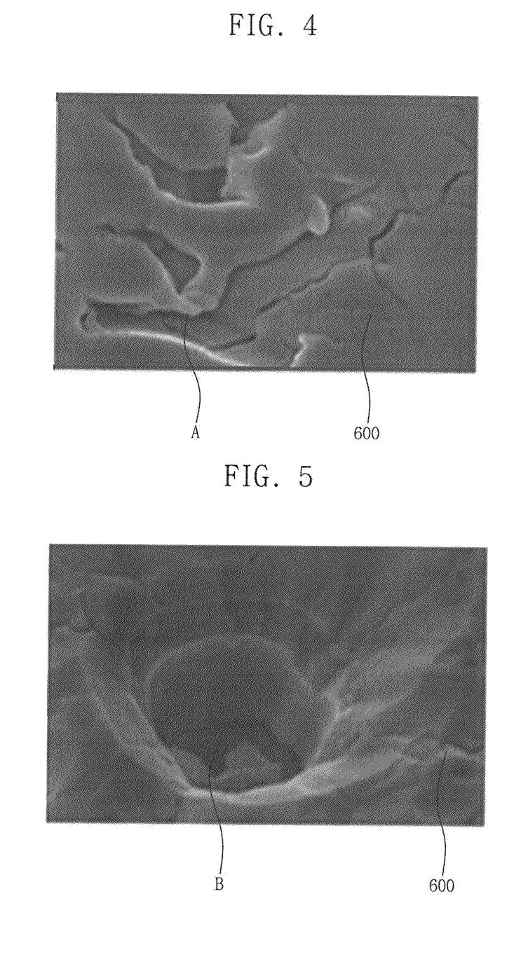

In the following FIGS. 4 and 5, and FIGS. 6 and 7, surface states of a conventional surface protection layer and a surface protection layer in accordance with embodiments of the present inventive concepts are illustrated, respectively.

A SEM image of an example surface structure of a conventional surface protection layer is illustrated in FIG. 4.

Referring to FIG. 4, the surface protection layer 600 is a dielectric coating layer formed by an air plasma spray (APS) method. The surface protection layer 600 is an yttrium oxide (e.g., Y₂O₃) layer.

As illustrated in FIG. 4, numerous cracks (e.g., reference symbol A) on a surface of the surface protection layer formed by the APS method may be seen. Numerous particles may be generated during a subsequent plasma etching process due to the above-described cracks A.

In FIG. 5, a SEM image of an example surface state after exposing the surface protection layer of FIG. 4 to a plasma etching environment is illustrated.

As illustrated in FIG. 5, when the surface protection layer 600 of FIG. 4 is exposed to a plasma etching environment for about 6 hours, the surface of the surface protection layer 600 becomes severely damaged. For example, a recessed area B denoted as reference symbol B may occur.

As described above, when a surface of a surface protection layer is damaged during a plasma etching process, numerous particles may be generated. Due to the particles, the inside of the plasma processing device may be contaminated, and an etch rate of a layer to be etched may be substantially decreased.

Further, device maintenance time and cost required to clean or replace a damaged window part and contaminated neighbor components may be increased.

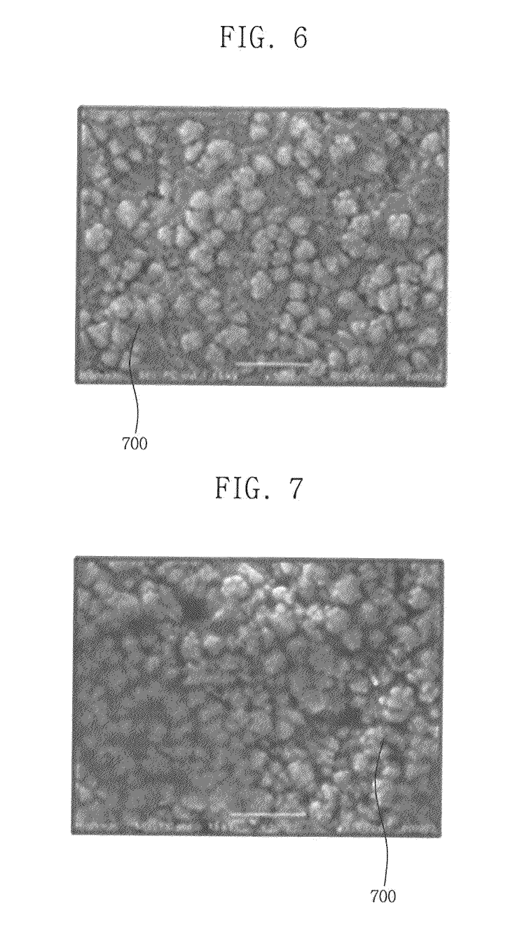

In FIG. 6, a SEM image of an example surface structure of a surface protection layer formed in accordance with embodiments of the present inventive concepts is illustrated.

Referring to FIG. 6, the surface protection layer 700 is a dielectric coating layer formed on a surface of a main material layer by a CVD method. The surface protection layer 700 is an yttrium oxide (e.g., Y₂O₃) layer formed by maintaining a process temperature at 100° C. or more. As described above, when a process temperature is maintained at 100° C. or more during a CVD process, a high density surface protection layer 700 with few, or no, air holes or cracks in its surface may be formed.

In FIG. 7, a SEM image of an example surface state after exposing the surface protection layer of FIG. 6 to a plasma etching environment is illustrated.

Referring to FIG. 7, a surface state after exposing the surface protection layer 700 to a plasma etching environment for about 5 hours is illustrated.

As illustrated in FIG. 7, the surface of the surface protection layer 700 according to embodiments of the present inventive concepts may be substantially undamaged when compared to the surface before being exposed to a plasma etching environment.

A high density surface protection layer formed by a CVD or a PVD method can maintain an excellent porosity and can have characteristics including a solid layer quality and a strong corrosion resistance. Thereby, the plasma processing device 10 may be undamaged or have reduced damage from an impact of ion sputtering having a high energy during a plasma etching process. Thus, the plasma processing device 10 has advantages of reducing particle generation and having a longer lifetime.

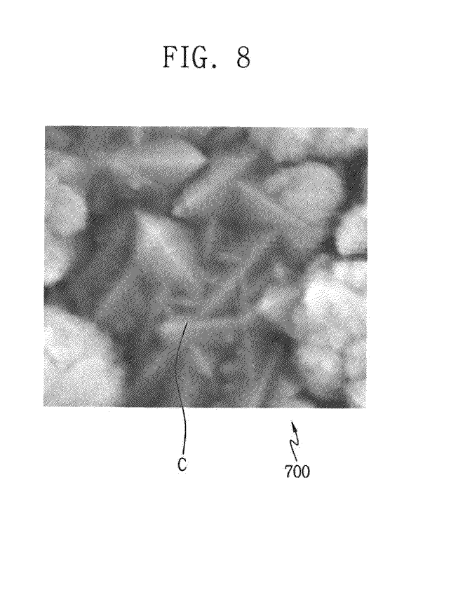

In FIG. 8, a SEM image of a surface state of a surface protection layer formed with a columnar structure is illustrated. The surface protection layer 700 is an yttrium oxide layer formed at a temperature of approximately 600° C.

As illustrated in FIG. 8, column shaped members can be formed on the surface of the surface protection layer 700. This structure having the column shaped members mutually arranged in an irregular shape is referred to as a columnar structure C.

A high density surface protection layer 700 in which the columnar structure is formed may decrease particle generation by ion sputtering during a plasma etching process by maintaining an excellent porosity and have a strong resistance to thermal stress applied to a window part 130.

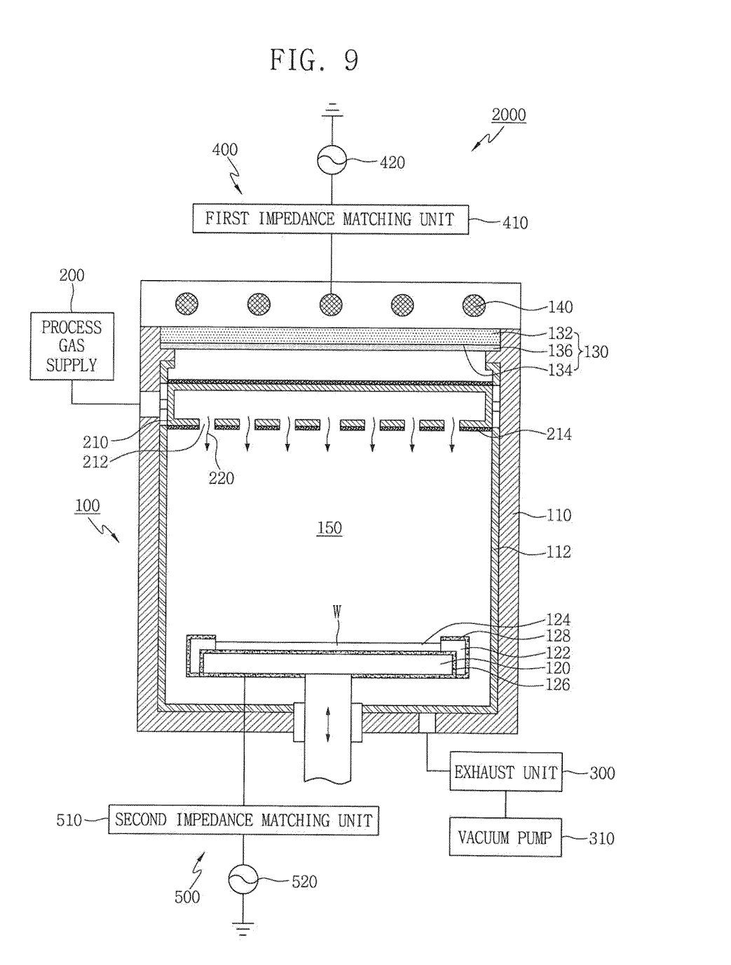

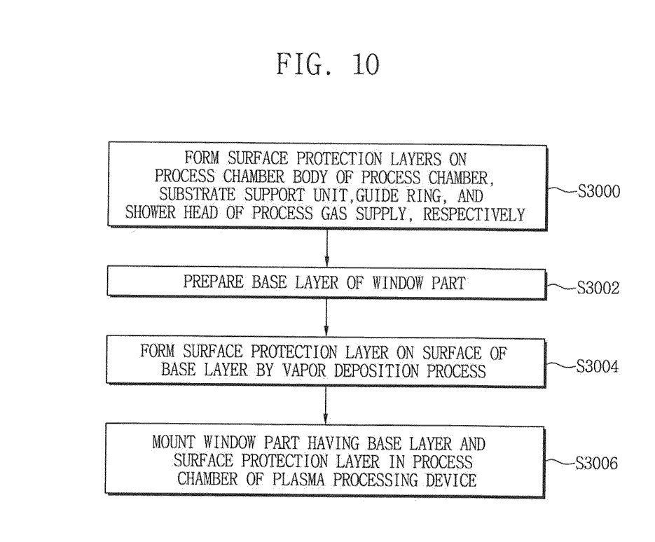

In FIG. 9, an overall block diagram of plasma processing devices 2000 in accordance with embodiments of the present inventive concepts is illustrated.

Referring to FIG. 9, plasma processing devices 2000 in accordance with embodiments of the present inventive concepts may include a process chamber 100, a process gas supply 200, an exhaust unit 300, an upper power supply 400, and a lower power supply 500.

The process chamber 100, the process gas supply 200, the exhaust unit 300, the upper power supply 400, and the lower power supply 500 included in the plasma processing device 2000 may have similar shapes and perform similar functions as those components having the same reference numbers that are included in the plasma processing device 10 illustrated in the FIG. 1.

A process chamber body 110 of the process chamber 100 may include a surface protection layer 112 on an inner surface thereof. The surface protection layer 112 may be formed on an inner sidewall and a lower surface of the process chamber body 110. The surface protection layer 112 may include a ceramic coating layer. The surface protection layer 112 may include an yttrium oxide (e.g., Y₂O₃) layer and/or a material layer containing carbon. The surface protection layer 112 may include a material layer having a porosity of 1% or less.

A substrate support unit 120 of the process chamber 100 may include a surface protection layer 126 on the substrate support unit 120. The surface protection layer 126 may include a ceramic coating layer. The surface protection layer 126 may include an yttrium oxide (e.g., Y₂O₃) layer and/or a material layer containing carbon. The surface protection layer 126 may include a material layer having a porosity of 1% or less.

A guide ring 122 of the process chamber 100 may include a surface protection layer 128 on the guide ring 122. The surface protection layer 128 may include a ceramic coating layer. The surface protection layer 128 may include an yttrium oxide (e.g., Y₂O₃) layer and/or a material layer containing carbon. The surface protection layer 128 may include a material layer having a porosity of 1% or less.

A shower head 210 of the process gas supply 200 may include a surface protection layer 214 on the shower head 210. The surface protection layer 214 may include a ceramic coating layer. The surface protection layer 214 may include an yttrium oxide (e.g., Y₂O₃) layer and/or a material layer containing carbon. The surface protection layer 214 may include a material layer having a porosity of 1% or less.

Methods of forming the plasma processing devices 2000 in accordance with embodiments of the present inventive concepts will be described with reference to FIGS. 9 and 10.

FIG. 10 is a flow chart illustrating methods of manufacturing plasma processing devices 2000 in accordance with embodiments of the present inventive concepts.

Referring to FIGS. 9 and 10, the methods of forming the plasma processing devices 2000 in accordance with embodiments of the present inventive concepts may include forming surface protection layers 112, 126, 128, and 214 on a process chamber body 110 of a process chamber 100, a substrate support unit 120, a guide ring 122, and a shower head 210 of a process gas supply 200, respectively (S3000).

Each of the surface protection layers 112, 126, 128, and 214 may include a ceramic coating layer. The surface protection layers 112, 126, 128, and 214 may include yttrium oxide (e.g., Y₂O₃) layers and/or material layers containing carbon. The surface protection layers 112, 126, 128, and/or 214 may include a material layer having a porosity of 1% or less. The surface protection layers 112, 126, 128, and/or 214 may be formed by chemical vapor deposition (CVD) or physical vapor deposition (PVD) method.

Referring to FIGS. 9 and 10, the method may include preparing a base layer 132 of window part 130 (S3002).

Referring to FIGS. 9 and 10, a window part 130 may be formed by depositing a surface protection layer 136 on a surface of the base layer 132 (S3004).

Referring to FIGS. 9 and 10, the window part 130 may be mounted inside the process chamber 100 of the plasma processing device 2000 (S3006).

In the above-described embodiments, a high density surface protection layer 112, 126, 128, 214 may also be formed on a process chamber body 110, a substrate support unit 120, a guide ring 122, and a shower head 210. Further, a window part 130 in which the high density surface protection layer 136 is formed is mounted on an upper portion of the process chamber body 110.

As a result, damage to a window part 130 caused by ion sputtering with a high energy may be reduced or prevented during a plasma etching process, and also damage to surfaces of the process chamber body 110, a substrate support unit 120, a guide ring, 122 and a shower head 210 may be prevented or reduced. An overall particle generation rate may also be decreased in the process chamber 100.

As described above, in accordance with embodiments of the present inventive concepts, a high density surface protection layer 136 with fewer air holes or cracks may be formed on a surface of a window part 130 mounted in a process chamber 100 of the plasma processing device 2000, or a surface protection layer 112, 126, 128, 214 may be formed on other neighbor components (e.g., the substrate support unit 120, the guide ring 122, and the shower head 210) in a process chamber and an inner wall of a process chamber body 110.

As a result, the window part 130 and other neighbor components mounted in the process chamber 100 may have an extended lifetime. Also, a contamination level in the process chamber 100 may be generally lowered, and thus, a device maintenance time required to clean and replace components may be reduced. Further, a particle generation rate may be decreased and an etch rate of a layer to be etched may be improved. As a result, reliability and yield of semiconductor devices may be improved.

In accordance with embodiments of the present inventive concepts, a solid surface protection layer 136 may be formed on a window part 130 of a plasma processing device 10 through a vapor deposition process (i.e., CVD or PVD). Thus, damage to the window part 130 by plasma may be reduced or prevented, particle generation in the plasma processing device 10 may be reduced or prevented, and the lifetime of the window part 130 may be extended.

Further, contamination in a plasma etching chamber may be reduced or prevented through the reduction of particle generation caused by damage to the window part 130. Thus, device maintenance time and cost required to clean and replace components may be reduced. Further, electrical characteristics and yield of semiconductor devices may be improved by improving an etch rate of a layer to be etched.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of these present inventive concepts as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A plasma processing device, comprising:
a process chamber body;
a substrate support unit in a lower portion of the process chamber body; and
a window part in an upper portion of the process chamber body,
wherein the window part comprises a base layer and a surface protection layer on the base layer and configured to face the substrate support unit, and
wherein the surface protection layer comprises an oxide having a columnar structure.

2. The plasma processing device of claim 1, wherein the base layer comprises a material layer having a surface roughness Rₐ of 1 μm or less.

3. The plasma processing device of claim 1, wherein the base layer comprises an aluminum oxide layer, an aluminum layer, a quartz layer, an oxide layer, and/or a nitride layer.

4. The plasma processing device of claim 1, wherein the surface protection layer comprises a ceramic coating layer.

5. The plasma processing device of claim 4, wherein the surface protection layer comprises an yttrium oxide layer.

6. The plasma processing device of claim 4, wherein the surface protection layer comprises a material layer containing carbon.

7. The plasma processing device of claim 1, wherein the surface protection layer comprises a material layer having a porosity of 1% or less.

8. The plasma processing device of claim 1, wherein the surface protection layer has a thickness of 5 μm to 30 μm.

9. The plasma processing device of claim 1, wherein the window part is configured to expose the surface protection layer to a processing space inside the process chamber body.

10. The plasma processing device of claim 1, wherein the window part is configured to form a ceiling of the process chamber body.

11. A plasma processing device, comprising:
a process chamber body; and
a window part in an upper portion of the process chamber body, configured to maintain a processing space of the process chamber body in a vacuum state, and
wherein the window part comprises a base layer and a surface protection layer on the base layer, and
wherein the surface protection layer comprises an oxide layer formed by a vapor deposition process.

12. The plasma processing device of claim 11, wherein the base layer comprises an aluminum oxide layer, an aluminum layer, a quartz layer, an oxide layer, and/or a nitride layer.

13. The plasma processing device of claim 11, wherein the surface protection layer comprises an yttrium oxide layer.

14. The plasma processing device of claim 11, wherein the surface protection layer comprises a material layer containing carbon.

15. The plasma processing device of claim 11, wherein the surface protection layer comprises a material layer having a columnar structure.

16. A plasma processing device, comprising:
a process chamber body having a first surface protection layer on a surface of the process chamber body; and
a window part in an upper portion of the process chamber body, the window part further comprising:
a base layer, and
a second surface protection layer on the base layer,
wherein the second surface protection layer comprises an oxide layer formed by a vapor deposition process.

17. The plasma processing device of claim 16, further comprising:
a substrate support unit on a lower portion of the process chamber body, and configured to support a wafer in a plasma etching process; and
a third surface protection layer on a surface of the substrate support unit.

18. The plasma processing device of claim 16, further comprising:
a substrate support unit on a lower portion of the process chamber body, and configured to support a wafer in a plasma etching process;
a guide ring that surrounds an edge portion of the substrate support unit; and
a third surface protection layer on a surface of the guide ring.

19. The plasma processing device of claim 16, further comprising:
a shower head configured to inject a process gas for plasma generation into the process chamber body; and
a third surface protection layer on a surface of the shower head.

20. The plasma processing device of claim 16, wherein the second surface protection layer comprises a material layer having a columnar structure.
